(19) United States
(12) Patent Application Publication
(10) Pub. No.: US 2020/0403110 A1
(43) Pub. Date: Dec. 24, 2020

(54) PHOTOVOLTAlC MODULE

(71) Applicant: NEWSOUTH INNOVATIONS PTY LIMITED, Sydney, New South Wales (AU)

(72) Inventors: Martin Andrew GREEN, Bronte, New South Wales (AU); Yajie Jessica JIANG, Caringbah, New South Wales (AU); Mark KEEVERS, Maroubra, New South Wales (AU); Nicholas EKINS-DAUKES, Kensington, New South Wales (AU); Zibo ZHOU, Rhodes, New South Wales (AU)

(21) Appl. No.: 16/975,380

(22) PCT Filed: Feb. 27, 2019
(86) PCT No.: PCT/AU2019/050164

§ 371 Date: Aug. 24, 2020

(30) Foreign Application Priority Data
Feb. 27, 2018 (AU) 2018900639

(51) Int. Cl. H01L 31/055; H01L 31/0216; H01L 31/0232; H01L 31/048; H02S 40/22; H01L 31/0288

(52) U.S. Cl. CPC H01L 31/055; H01L 31/02168; H01L 31/02327; G02B 1/11; H02S 40/22; H01L 31/0288; H01L 31/048

(57) ABSTRACT

The present disclosure provides a photovoltaic module comprising a photon absorbing material for absorbing electromagnetic radiation. The photon absorbing material comprises solar cells and a glass material. The photovoltaic module also comprises an anti-reflective coating that has anti-reflective properties in a first wavelength range and reflective properties in a second wavelength range. The anti-reflective coating is positioned over the glass material. The anti-reflective coating comprises a layered structure that has layers that together have an out-of-sequence or non-graded refractive index profile. The present disclosure also provides a selective reflector comprising a layer of a glass material that is largely transmissive for visible light and comprises dopants that absorb incident electromagnetic radiation in a wavelength range at a centre wavelength, which is within a wavelength range at which the atmosphere of the Earth absorbs electromagnetic radiation strongly and more strongly than in an adjacent wavelength range. The refractive index of the glass material at and around the centre wavelength is altered by the strong absorption of the dopants such that the reflectance of the glass material within at least a portion of the first wavelength range is increased if that portion of the first wavelength range is adjacent to the centre wavelength.

### TECHNICAL FIELD OF THE INVENTION

The present invention relates to a photovoltaic module.

### BACKGROUND OF THE INVENTION

Photovoltaic modules are now used for various applications. It is known that the conversion efficiency of photovoltaic modules is adversely affected if the temperature of the photovoltaic modules increases. Photovoltaic modules often operate in bright sunlight, typically 20-30° C. above ambient temperature. This not only reduces the energy production of a photovoltaic module by 0.4-0.5% (relative) for every degree increase in temperature (up to 15% for a 30° C. increase in temperature), but also accelerates all known degradation processes and reduces the lifespan of the photovoltaic module below a lifespan that is otherwise achievable.

In addition, photovoltaic modules typically degrade 0.5% (relative) in output for each year in the field, with photovoltaic modules normally warranted to be above 80% of their initial rating after 25 years of field exposure. Further, long time testing of specific degradation modes suggest degradation rates approximately double for every 10° C. increase in temperature. This suggests that photovoltaic modules operating at a temperature lower than the above-mentioned typical operating temperature could not only increase their energy production, but could also have a reduced degradation and could consequently be used for extended periods of time than otherwise possible.

### SUMMARY OF THE INVENTION

In accordance with a first aspect of the present invention there is provided a wavelength selective reflector comprising a material that is largely transmissive for light within a first wavelength range and comprises dopants, the dopants being selected to absorb incident electromagnetic radiation in a second wavelength range that is narrower than the first wavelength range and centred at, or includes, a centre wavelength at which the atmosphere of the Earth absorbs electromagnetic radiation strongly and more strongly than in an adjacent wavelength range;

wherein the refractive index of the material at and around the centre wavelength is altered by the strong absorption by the dopants such that the reflectance of the material within at least a portion of the first wavelength range is increased if that portion of the first wavelength range is adjacent, such as immediately adjacent, to the centre wavelength.

The material may be provided in various forms. For example, the material may comprise a glass material which includes the dopants. Alternatively, the material may for example be provided in the form of a layer or film that is applied to a component, such as a glass material. The material may form a part of a photovoltaic module and may for example be provided in the form of a glass sheet that is positioned over the photon absorbing material. Alternatively, the material may be provided in the form of a layer that is applied to a surface of the glass sheet, such as a rear (or front) surface of the glass sheet of the photovoltaic module.

The centre wavelength is typically a wavelength at which the atmosphere of the Earth has an absorption band.

In one embodiment the material comprises low iron glass. The dopants may be selected such that, at the centre wavelength, the material has a refractive index that is modified substantially from the refractive index of low iron glass (circa 1.5).

The dopants and the dopant concentration typically are selected such that there is a resonant modification of the refractive index of the doped material at the centre wavelength. Further, the dopants typically are selected such that the dopants do not absorb, or only absorb an insignificant amount, of radiation within a wavelength band that extends past the atmospheric absorption band.

The refractive index of the doped material is decreased at a lower wavelengths side of the refractive index resonance within a wavelength range of at least a few hundred nanometres. The refractive index may, in a direction from lower wavelengths towards the centre wavelength, decrease to a minimum that could, in principle, be even negative at resonant enhancement of the refractive index. This decrease of the refractive index has the advantage that a mismatch of refractive index between the material and ambient air is reduced within that wavelength range. This reduction in mismatch of refractive index between the material and ambient air reduces the reflectance of the material. The selective reflector can consequently be designed such that reflection of radiation within a specific wavelength range is reduced. For example, the specific wavelength range may include a wavelength range of incident light that can be converted into electricity (for example using a solar cell).

Further, the refractive index of the doped material is increased at a higher wavelengths side of the resonant enhancement of the refractive index within a wavelength range of at least a few hundred nanometres. The refractive index may, in a direction from higher wavelengths towards the centre wavelength, increase to a maximum of for example +∞ at the resonant enhancement of the refractive index. This increase of refractive index at the higher wavelength side increases mismatch of the refractive index between the material and ambient air. This has the advantage that the reflectance of the material is increased, and it is possible to design the selective reflector such that an absorption of thermal energy of the selective reflector is reduced. For example, the material may be glass and the resonant modification of the refractive index may be centred at a wavelength of approximately 1400 nm and the selective reflector may be arranged such that within a selected wavelength range the refractive index is increased to 2 (for example) and the reflection of the glass material is increased from 4% (for uncoated glass material) to 11%.

The selective reflector may also comprise an anti-reflective coating that has anti-reflective properties that depend on the refractive index of the material. In one specific embodiment the anti-reflective coating has stronger anti-reflective properties for lower refractive indices of the material and weaker anti-reflection properties for higher refractive indices of the material.

The centre wavelength may be a wavelength at which the atmosphere of the Earth strongly absorbs electromagnetic radiation due to the presence of water vapour, carbon dioxide or other molecules.

In one specific example the centre wavelength is approximately 1400 nm.

The material may be doped with any suitable material that absorbs light strongly in a narrow wavelength range including or centred at the centre wavelength, such as a suitable metallic element or molecules including hydroxyl groups.

In accordance with a second aspect of the present invention there is provided a photovoltaic module comprising:

a photon absorbing material for absorbing electromagnetic radiation, the photon absorbing material comprising a solar cell;

a glass material; and

an anti-reflective coating having anti-reflective properties in a first wavelength range and reflective properties in a second wavelength range, the anti-reflective coating being positioned over the glass material whereby the glass material is positioned between the anti-reflective coating and the photon absorbing material, the anti-reflective coating comprising a layered structure having layers that together have an out-of-sequence or non-graded refractive index profile.

In one embodiment the second wavelength range includes an infrared wavelength range. In a specific example the second wavelength range is a wavelength range above 1200 nm. For example, the second range may range from 1200 nm to 4000 nm. The first wavelength range typically includes a wavelength range of visible light and the photon absorbing material typically is arranged to absorb electromagnetic radiation within a wavelength range of visible light.

The layered structure may be a thin-film structure and may comprise multiple layers. The thin-film structure may comprise any number of layers, but in one specific embodiment comprises less than 7 layers and typically less than 5 layers. Each layer may be formed from a material having a refractive index ranging from 1.2 to 2.8.

Particularly interesting are layers made from material of different porosity to produce these changes in refractive index, with porous layers of SiO₂ of particular interest due to their current use as a single layer coating on solar modules, as well as porous layers of TiO₂, already used in self-cleaning glass.

In accordance with a third aspect of the present invention there is provided a photovoltaic module comprising:

a photon absorbing material for absorbing received electromagnetic radiation, the photon absorbing material comprising a solar cell; and

the selective reflector in accordance with the first aspect of the present invention.

The selective reflector may be provided in the form of a glass cover sheet comprising a doped glass material being positioned over the photon absorbing material. Alternatively, the selective reflector may for example be provided in the form of a layer that is applied to a surface of the glass sheet, such as a rear (or front) surface of the glass sheet of the photovoltaic module.

The photovoltaic module may also comprise an anti-reflective coating, which may be located on a front surface of the glass material.

### BRIEF DESCRIPTION OF THE DRAWINGS

Embodiments of the invention will now be described, by way of example, with reference to the accompanying drawings in which:

FIG. 1 is a selective reflector in accordance with an embodiment of the present invention;

FIG. 2 is a graph of refractive index as a function of wavelength simulated for glass being doped with an absorber that absorbs electromagnetic radiation at a wavelength of 1400 nm;

FIG. 3 is a graph of absorption and reflection as a function of wavelength simulated for the glass being doped with an absorber that absorbs electromagnetic radiation at a wavelength of 1400 nm; and

FIG. 4 is a schematic representation of a photovoltaic module in accordance with an embodiment of the present invention.

### DETAILED DESCRIPTION OF EMBODIMENTS

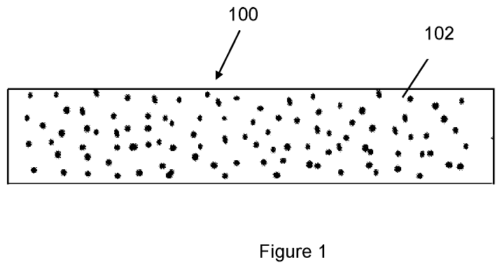

FIG. 1 shows a selective reflector 100 in accordance with an embodiment of the present invention. The selective reflector 100 has dopant material 102 incorporated into a material, which in this example is soda lime glass. The dopant material comprises atoms, molecules or ions that are distributed throughout the glass material. In this embodiment the dopants are molecules that have hydroxyl groups and absorb electromagnetic radiation at a wavelength of approximately 1400 nm. However, a person skilled in the art will appreciate that alternatively the material may be doped with other suitable materials, such as suitable metallic materials, that may absorb electromagnetic radiation at different wavelengths. Further, the material may be provided in various forms. For example, in an alternative embodiment that material may be provided in the form of a layer of film that is applied to another component.

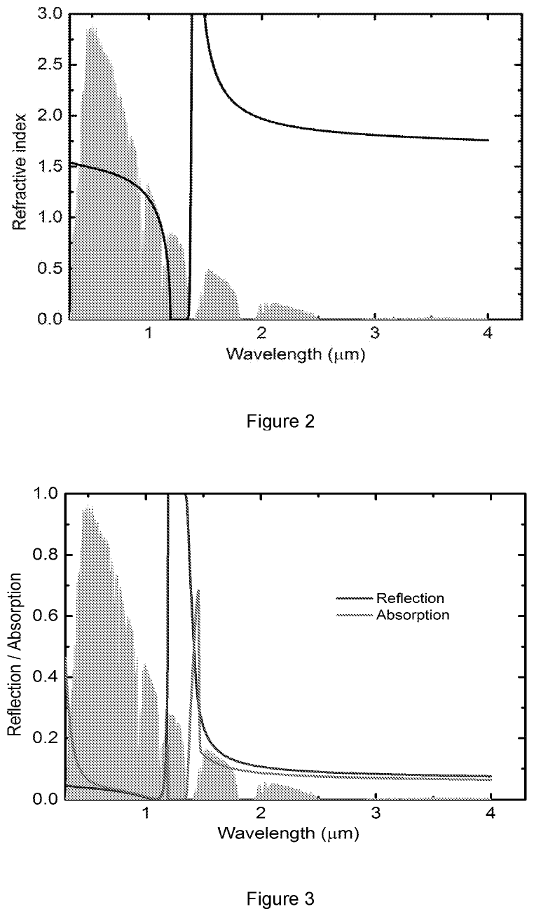

FIG. 2 shows a simulation of the refractive index of the glass material of the selective reflector 100 as a function of wavelength and FIG. 3 shows the corresponding simulated reflection and absorption. In this example the glass material is doped with a material having strong (resonant) absorption at a wavelength of 1400 nm. The refractive index of the glass is up to a wavelength of approximately 500 nm approximately 1.5, and then decreases ideally towards −∞ at 1400 nm. Further, the refractive index increases from above 1.5 at 2500 nm with decreasing wavelength ideally towards +∞ at 1400 nm. Absorption over a narrow but finite wavelength range by the dopants will smooth out these features while retaining their key attributes.

By altering the refractive index of the glass, its reflection properties can be controlled. With such doped glass, a reflector having a refractive index variation as shown in FIG. 2 will be largely transparent at wavelength ranges for which the refractive index is 1.5, but will, as illustrated in FIG. 3, show increased reflection for wavelengths above approximately 1200 nm increasing to strong reflection near 1400 nm and subsequently decreasing reflectivity to a wavelength of approximately 2500 nm although still higher than if the refractive index had remained at 1.5.

The selective reflector 100 absorbs and reflects electromagnetic radiation strongly at a wavelength of approximately 1400 nm. Water and carbon dioxide molecules in the atmosphere of the Earth also absorb electromagnetic radiation at this wavelength (or near this wavelength), and consequently negligible sunlight having a wavelength of 1400 nm will be incident on the reflector 100 when the reflector 100 is exposed to sunlight in air.

The strong reflectivity of the reflector 100 exactly at 1400 nm is not of particular advantage (and the associated absorption is also not of disadvantage) as the reflector will only receive a very small portion (or no) electromagnetic radiation at that wavelength when the reflector 100 is exposed to sunlight in air, but as the reflector 100 also has increased reflectivity within a wavelength range around 1400 nm (significant reflection at a wavelength within a few 100 nm of 1400 nm), the reflector 100 is useful for reflecting infrared radiation, which reduces absorption of thermal energy by the solar cell and consequently results in a lower operating temperature of the solar cell. For example, if the resonant enhancement of the refractive index is centred at a wavelength of approximately 1400 nm, the selective reflector may be arranged such that within a specific wavelength range the refractive index is increased to 2 (for example) and the reflection of the glass material is increased from 4% (for uncoated glass material) to 11%.

The selective reflector 100 may consequently be used to reflect infrared radiation and may be used as a component of a photovoltaic module in order to reflect incident infrared radiation, which would otherwise increase the temperature of the photovoltaic device and would decrease efficiency and lifespan.

Further, the reflector also has reduced reflectivity at the lower wavelengths side within a wavelength range around 1400 nm (significant reflection at a wavelength within a few 100 nm of 1400 nm). The resonant modification of the refractive index at the centre wavelength results in a decrease of the refractive index at the lower wavelength side of the refractive index resonance. The refractive index may, in a direction from lower wavelength towards the centre wavelength and within a few hundred nanometres, decrease to ideally −∞ at the centre wavelength. Because of the decreased refractive index, a mismatch in refractive index between the glass material and ambient air is reduced. The reduction in refractive index mismatch results in reduced reflectance of the glass material for that lower wavelength range. For example, the selective reflector can be designed such that reflection of radiation that may be converted into electricity (for example using a solar cell) is reduced.

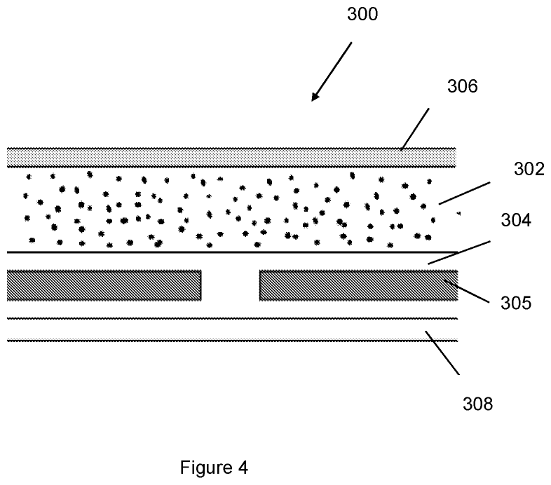

FIG. 4 shows a photovoltaic module 300 in accordance with an embodiment of the present invention. The photovoltaic module 300 comprises a glass material 302, which in this embodiment is provided in the form of the above-described selective reflector 100. The glass material 302 is coated with an anti-reflective coating 306. Further, the photovoltaic module 300 comprises a transparent encapsulant material 304, which encapsulates solar cells 305. A rear cover sheet 308 covers the photon absorbing material.

FIG. 4 only illustrates the photovoltaic module 300 schematically and does not show all components of the photovoltaic module 300 (for example, electrical contacts and further layers are not shown). A person skilled in the art will appreciate that the photovoltaic module 300 may be provided in various forms.

Further, the illustrated embodiment includes the wavelength selective reflector in the form of the glass material 302. In an alternative embodiment the selective reflector may instead be provided in the form of a layer of film that is applied for example to a glass material that may form a glass sheet of a photovoltaic module. In the case the layer of film may for example be applied to a rear side of the glass material whereby the layer of film is at least partially protected from UV radiation.

The antireflective coating 306 has anti-reflective properties in a first wavelength range that includes the visible wavelength range and reflective properties in a second wavelength range, which includes an infrared wavelength range. The anti-reflective coating is a layered structure having in this embodiment 4 or 5 layers. The layers have refractive indices chosen so that the layers together have an out-of-sequence or non-graded refractive index profile. In this example the layers have refractive indices ranging from 1.2 to 2.8.

In one specific example the layers are formed from a material of different porosity to produce the variations in refractive index. In this embodiment the layers comprise porous SiO₂ or TiO₂.

In a specific example the second wavelength range is above approximately 1200 nm. For example, the second wavelength range may range from 1200 nm to 2000 nm. The first wavelength range typically includes a wavelength range of visible light.

Both the reflective properties of the glass material 302, provided in the form of the reflector 100 discussed above, and the reflective properties of the antireflective coating 306 in the infrared wavelength range contribute to a reduction of the operating temperature of the photovoltaic module 300, which increases conversion efficiency and reduces degradation and thereby extends the lifespan of the photovoltaic module 300.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A selective reflector comprising a material that is largely transmissive for light within a first wavelength range and comprises dopants, the dopants being selected to absorb incident electromagnetic radiation in a second wavelength range that is narrower than the first wavelength range and centred at, or includes, a centre wavelength at which the atmosphere of the Earth absorbs electromagnetic radiation strongly and more strongly than in an adjacent wavelength range;
wherein the refractive index of the material at and around the centre wavelength is altered by the strong absorption of the dopants such that the reflectance of the material within at least a portion of the first wavelength range is increased if that portion of the first wavelength range is adjacent to the centre wavelength.

2. The selective reflector of claim 1 wherein the material comprises a glass material which includes the dopants.

3. The selective reflector of claim 1 wherein the material is provided in the form of a layer or film that is applied to a component.

4. The reflector of claim 1 wherein the centre wavelength is a wavelength at which the atmosphere of the Earth has an absorption band.

5. The reflector of claim 1 wherein the first wavelength range is immediately adjacent to the centre wavelength range.

6. The reflector of claim 1 wherein the material comprises a low iron glass material and wherein the dopants are selected such that, at the centre wavelength, the glass has a refractive index that is modified substantially from the refractive index of low iron glass (circa 1.5).

7. The reflector of claim 1 wherein the dopants selected such that the dopants do not absorb, or only absorb an insignificant amount, of radiation within a wavelength band that extends past the atmospheric absorption band.

8. The reflector of claim 1 wherein the refractive index of the doped material is decreased at a lower wavelengths side of the refractive index resonance within a wavelength range of at least few hundred nanometres.

9. The reflector of claim 1 wherein the refractive index of the doped material is increased at a higher wavelengths side of the refractive index resonance within a wavelength range of at least few hundred nanometres.

10. The reflector of claim 1 wherein the centre wavelength is a wavelength at which the atmosphere of the Earth absorbs electromagnetic radiation.

11. The reflector of claim 1 wherein the centre wavelength is approximately 1400 nm.

12. The reflector of claim 1 wherein the material is doped with a metallic element.

13. The reflector of claim 1 wherein the material is doped with molecules including hydroxyl groups.

14. A photovoltaic module comprising:
a photon absorbing material for absorbing electromagnetic radiation and comprising solar cells;
a glass material;
an anti-reflective coating having anti-reflective properties in a first wavelength range and reflective properties in a second wavelength range, the anti-reflective coating being positioned over the glass material whereby the glass material is positioned between the anti-reflective coating and the photon absorbing material, the anti-reflective coating comprising a layered structure having layers that together have an out-of-sequence refractive index profile.

15. The photovoltaic module of claim 14, wherein the second wavelength range includes an infrared wavelength range.

16. The photovoltaic module of claim 14 wherein the second wavelength range is a wavelength range above 1200 nm and wherein the first wavelength range includes a wavelength range of visible light.

17. The photovoltaic module of claim 14 wherein the layered structure is a thin-film structure comprising 3-5 layers.

18. The photovoltaic module of claim 14 wherein the layers comprise one or more materials of different porosity to produce the changes in refractive index.

19. The photovoltaic module of claim 18 wherein the porous material comprises SiO₂ or TiO₂.

20. A photovoltaic module comprising:
a photon absorbing material for absorbing received electromagnetic radiation, the photon absorbing material comprising a solar cell; and
the reflector of claim 1.

21.-22. (canceled)
